(19) United States
(12) Patent Application Publication
(10) Pub. No.: US 2025/0357161 A1
(43) Pub. Date: Nov. 20, 2025

(54) DYNAMIC PROCESSING CHAMBER BAFFLE

(71) Applicant: Applied Materials, Inc., Santa Clara, CA (US)

(72) Inventor: Udit Suryakant Kotagi, Singapore (SG)

(73) Assignee: Applied Materials, Inc., Santa Clara, CA (US)

(21) Appl. No.: 18/663,708

(22) Filed: May 14, 2024

(51) Int. Cl. H01L 21/67; H01L 21/02

(52) U.S. Cl. CPC H01L 21/6719; H01L 21/02205; H01L 21/67017

(57) ABSTRACT

Exemplary semiconductor processing systems may include a chamber body having sidewalls and a base. The chamber body may define a processing region. The chambers may include a substrate support extending through the base of the chamber body. The substrate support may be configured to support a substrate within the processing region. The chambers may include a faceplate defining a plurality of apertures through the faceplate. The faceplate may define the processing region from above. The chambers may include a pumping ring extending about the processing region and providing an exhaust path from the processing region. The chambers may include a radial baffle extending about the faceplate. The radial baffle may be translatable between a first position in which the radial baffle is retracted radially away from the faceplate and a second position in which the radial baffle is extended radially toward the processing region.

### TECHNICAL FIELD

The present technology relates to components and apparatuses for semiconductor manufacturing. More specifically, the present technology relates to processing chamber components and other semiconductor processing equipment, as well as methods of operation.

### BACKGROUND OF THE INVENTION

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### BRIEF SUMMARY OF THE INVENTION

Exemplary semiconductor processing systems may include a chamber body having sidewalls and a base. The chamber body may define a processing region. The chambers may include a substrate support extending through the base of the chamber body. The substrate support may be configured to support a substrate within the processing region. The chambers may include a faceplate defining a plurality of apertures through the faceplate. The faceplate may define the processing region from above. The chambers may include a pumping ring extending about the processing region and providing an exhaust path from the processing region. The chambers may include a radial baffle extending about the faceplate. The radial baffle may be translatable between a first position in which the radial baffle is retracted radially away from the faceplate and a second position in which the radial baffle is extended radially toward the processing region.

In some embodiments, when the radial baffle is in the first position, an inner edge of the radial baffle may be disposed radially outward of an inner edge of the pumping ring. When the radial baffle is in the second position, the inner edge of the radial baffle may be disposed radially inward of the inner edge of the pumping ring. The radial baffle may include an annular shape. The radial baffle may be translatable to a plurality of radial positions between the first position and the second position. In the second position, an inner edge of the radial baffle may be spaced apart from an outer surface of the faceplate by a distance of between 15 mils and 30 mils. The radial baffle may include a dielectric material. The chambers may include an actuator that is coupled with the radial baffle. The actuator may be configured to translate the radial baffle between the first position and the second position. The actuator may include at least one of a hydraulic actuator, a pneumatic actuator, or a linear actuator. The pumping ring may define a plurality of pumping apertures that extend through an upper surface of the pumping ring and that are fluidly coupled with the exhaust path.

Some embodiments of the present technology may encompass methods of semiconductor processing. The methods may include delivering a deposition precursor into a processing region of a semiconductor processing chamber. The methods may include depositing a layer of material on a substrate disposed within the processing region. The processing region may be maintained at a first pressure during the depositing. The methods may include extending a radial baffle into the processing region in a radially inward direction. The radial baffle may modify an exhaust flow path within the processing region. The methods may include forming a plasma of a treatment precursor within the processing region. The processing region may be maintained at a second pressure during the forming. The methods may include treating the layer of material deposited on the substrate with plasma effluents of the treatment precursor.

In some embodiments, the radial baffle may be retracted while the layer of material is deposited on the substrate. The first pressure may be at least 50 Torr. The second pressure may be no greater than 20 Torr. The methods may include subsequent to depositing the layer of material on the substrate, moving the substrate towards a faceplate of the semiconductor processing chamber. Extending the radial baffle into the processing region may include extending the radial baffle only a portion of a distance to a peripheral edge of a faceplate through which the deposition precursor is delivered.

Some embodiments of the present technology may encompass methods of semiconductor processing that may include performing a first processing operation on a substrate disposed within a processing region of a processing chamber. The first processing operation may be performed at a first pressure. The methods may include adjusting a radial position of an inner edge of a radial baffle within the processing region relative to a peripheral edge of a faceplate of the processing chamber to modify an exhaust flow path within the processing region. The methods may include performing a second processing operation on the substrate. The second processing operation may be performed at a second pressure that is different than the first pressure.

In some embodiments, the methods may include flowing a first precursor into the processing region via the faceplate. The first precursor may be used when performing the first processing operation. The methods may include flowing a second precursor into the processing region via the faceplate. The second precursor may be used when performing the second processing operation. The first pressure may be higher than the second pressure. Adjusting the radial position of the inner edge of the radial baffle may include extending the inner edge of the radial baffle in a radially inward direction toward a peripheral edge of the faceplate. The first pressure may be lower than the second pressure. Adjusting the radial position of the inner edge of the radial baffle may include retracting the inner edge of the radial baffle in a radially outward direction away from a peripheral edge of the faceplate. One of the first pressure and the second pressure may be at least 50 Torr and the other of the first pressure and the second pressure may be no greater than 20 Torr. The first processing operation may include one of deposition, etch, treat, anneal; and the second processing operation may include a different one of deposition, etch, treat, anneal.

Such technology may provide numerous benefits over conventional systems and techniques. For example, embodiments of the present technology may allow a treatment process to be performed in the same chamber in which deposition occurred. Additionally, the components may allow modification to accommodate any number of chambers or processes to improve uniformity of processing. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top view of an exemplary processing system according to some embodiments of the present technology.

FIG. 2 shows a schematic cross-sectional view of an exemplary plasma system according to some embodiments of the present technology.

FIGS. 3A-3B show a schematic cross-sectional views of an exemplary processing system according to some embodiments of the present technology.

FIGS. 4A-4C show a schematic views of an exemplary radial baffle according to some embodiments of the present technology.

FIG. 5 shows schematic edge effects for exemplary baffles according to some embodiments of the present technology.

FIG. 6 shows operations of an exemplary method of semiconductor processing according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Deposition processes in semiconductor processing may be performed in a number of ways, including thermally or plasma enhanced chemical vapor deposition. Processes that may be used to fill high aspect ratio features may include precise chamber configurations and processing conditions to perform the filling operations. For example, sub-atmospheric chemical vapor deposition may include a thermally-activated deposition occurring at relatively high chamber pressures. Once the deposition has occurred, a second operation may be performed to treat the deposited material, such as to densify the film, for example, as well as to improve gapfill performance.

As device features reduce in size, tolerances across a substrate surface may be reduced, and chamber configurations may affect device realization and uniformity. Conventional technologies have been unable to adequately treat materials deposited by sub-atmospheric chemical vapor deposition. For example, the deposition chamber is typically optimized for high-pressure and high flow operations. Any changes to flow, pressure, or spacing can create asymmetries in the resulting film properties. For example, the treatment process, may often include a plasma process performed at much lower pressure. Performing such high and low pressure processing operations in a single chamber may result in deposition non-uniformity, such as planar uniformity issues, on the wafer due to processing characteristics associated with the different pressures. For example, if the plasma process was attempted in the deposition chamber, the reduced flow rate may lead to precursors being immediately pumped from the chamber through exhaust systems configured for high-flow operation. Additionally, some systems include chambers with shared pumping between the chambers, which causes asymmetric pumping within each chamber. To accommodate this asymmetry, pumping liners, which may extend about the processing region, may be characterized by asymmetric exhaust aperture formation, which may balance the exhaust from the chamber. However, this setup may be incapable of balancing low-flow exhaust, which may fail to reduce conductance of the flow and cause non-uniform exhaust, and which may lead to non-uniform processing on the substrate. Consequently, conventional technologies have been forced to perform treatments in separate chambers optimized for low flow, as changes to existing chamber hardware are typically unable to provide uniform flow characteristics in both high and low pressure settings. The use of separate high and low pressure chambers leads to increased queue time and potential vacuum break.

The present technology overcomes these challenges by utilizing a chamber setup including a retractable radial baffle that enables the processing volume to be modified. This adjustable configuration, which may be adjusted in situ, may provide dynamic control over chamber conductance. By increasing residence time of low-flow precursors and reducing conductance from the chamber to the exhaust, the baffle and chamber configuration may accommodate high-pressure processing as well as low-pressure processing. Accordingly, the present technology may improve uniformity of processing during separate operations, as well as allow single-chamber processing to be performed at different pressure regimes.

Although the remaining disclosure will routinely identify specific deposition and treatment processes utilizing the disclosed technology, it will be readily understood that the systems and methods are equally applicable to other deposition, etching, and cleaning chambers, as well as processes as may occur in the described chambers. Accordingly, the technology should not be considered to be so limited as for use with these specific deposition processes or chambers alone. The disclosure will discuss one possible system and chamber that may include a baffle system according to embodiments of the present technology before additional variations and adjustments to this system according to embodiments of the present technology are described.

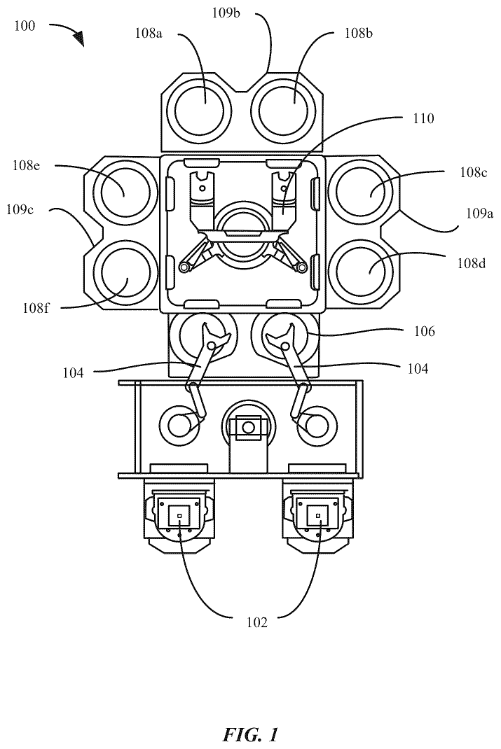

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100. Because the processing chambers may be included as pairs, each paired set of chambers may include a single pumping system including a single access for each chamber.

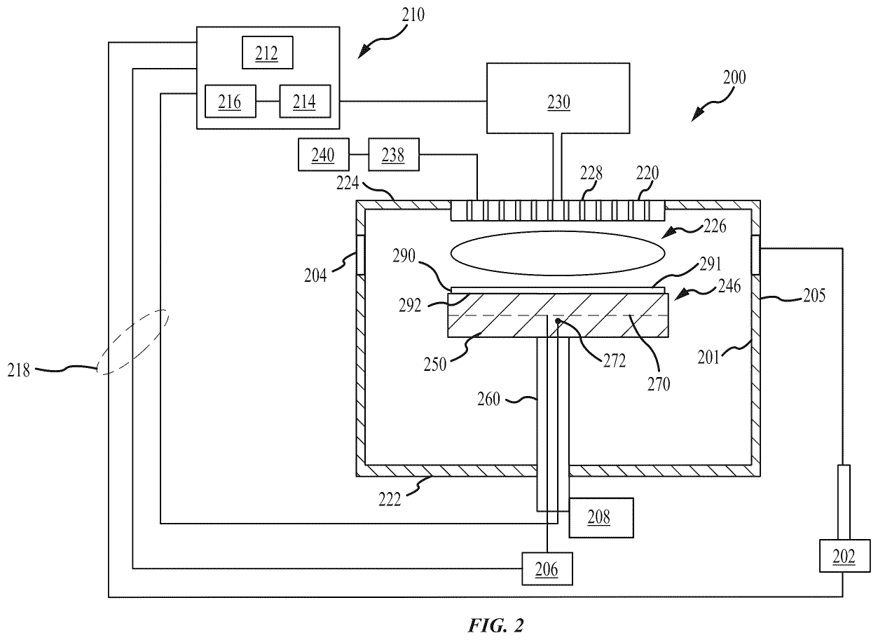

FIG. 2 shows a schematic cross-sectional view of an exemplary semiconductor processing system 200 according to some embodiments of the present technology, and which may include one of a paired set of chambers, or which may be incorporated as a standalone chamber. However, it is to be understood that the present technology may be applicable to any type of chamber, including single standalone chambers, twin chambers, quad chambers, or any other chamber setup. The figure may illustrate an overview of systems incorporating one or more aspects of the present technology as described further below, and/or which may be specifically configured to perform one or more operations according to embodiments of the present technology. Additional details of the system 200, such as an incorporated baffle, and methods performed within the chamber or any other chamber, are described further below. However, it is to be understood that the methods may similarly be performed in any system within which multiple pressure regimes may be accommodated as discussed throughout the present disclosure.

Semiconductor processing system 200 may include semiconductor processing chamber 205, which may include a top wall 224 or lid, a sidewall 201, and a bottom wall 222 that may define a substrate processing region 226 and may form a chamber body. A gas panel 230 and a controller 210 may be coupled with the process chamber 205. A substrate support assembly 246 may be provided in the substrate processing region 226 of the process chamber 205. The substrate support assembly 246 may include an electrostatic chuck 250 supported by a stem 260. The electrostatic chuck 250 may be fabricated from aluminum, ceramic, and other suitable materials such as stainless steel. The electrostatic chuck 250 may be moved inside the process chamber 205 using a mechanism 208 allowing relative changes in position between the showerhead and the wafer. For example, the relative position between the showerhead and the substrate can be adjusted in chambers according to embodiments of the present technology. A power source 206 may be used to facilitate electrostatic chucking during processing operations. A temperature sensor 272, such as a thermocouple, may be embedded in the electrostatic chuck 250 to monitor the temperature of the electrostatic chuck 250. The measured temperature may be used by the controller 210 to control the power supplied to the heater element 270 to maintain the substrate at a desired temperature.

A vacuum pump 202 may be coupled with the processing chamber, as well as a tandem pair chamber as previously described. The vacuum pump 202 may be used to maintain a desired gas pressure in the process chamber 205. The vacuum pump 202 may also evacuate post-processing gases and byproducts of the process from the process chamber 205. The vacuum pump may be coupled with a pumping ring 204, or liner, which may extend about the chamber body. The pumping ring may define a number of apertures in any configuration or size and may allow gases and other materials to be uniformly drawn from the chamber.

A gas distribution assembly 220, which may be or include a showerhead and/or faceplate, having a plurality of apertures 228 may be disposed on the top of the process chamber 205 above the electrostatic chuck 250. The apertures 228 of the gas distribution assembly 220 may be utilized to introduce process gases, such as deposition precursors or oxidation precursors, into the process chamber 205. The apertures 228 may have different sizes, number, distributions, shapes, designs, or diameters to facilitate the flow of the various process gases for different process requirements. The gas distribution assembly 220 may be connected to the gas panel 230, such as with a delivery pipe, which may allow various gases to flow to the processing volume 226 during processing. A plasma may be formed from the process gas mixture exiting the gas distribution assembly 220 to enhance the thermal decomposition and/or ionization of the process gases resulting in the deposition or formation of a material on a top surface 291 of a substrate 290 positioned on the electrostatic chuck 250.

The gas distribution assembly 220 and the electrostatic chuck 250 may form a pair of spaced apart electrodes in the processing volume 226. One or more RF power sources 240 may provide a plasma power through a matching network 238, which may be optional, to the gas distribution assembly 220 to facilitate generation of plasma between the gas distribution assembly 220 and the electrostatic chuck 250. Alternatively, the RF power source 240 and the matching network 238 may be coupled with the gas distribution assembly 220, the electrostatic chuck 250, coupled with both the gas distribution assembly 220 and the electrostatic chuck 250, or coupled with an antenna disposed exterior to the process chamber 205. In some embodiments, the RF power source 240 may produce power at a frequency of greater than or about 100 KHz, greater than or about 500 KHz, greater than or about 1 MHz, greater than or about 10 MHZ, greater than or about 20 MHz, greater than or about 50 MHz, greater than or about 100 MHZ, among other frequency ranges. Specific examples of frequencies of the power produced by RF power source 240 include 350 KHz, 2 MHZ, 13.56 MHz, 27 MHz, 40 MHz, 60 MHz, 100 MHZ, and 162 MHz, among other frequencies.

The controller 210 may include a central processing unit (“CPU”) 212, a memory 216, and a support circuit 214, which may be utilized to control the process sequence and regulate the gas flows from the gas panel 230. The CPU 212 may be of any form of a computer processor that may be used in an industrial setting. The software routines may be stored in the memory 216, such as random-access memory, read only memory, floppy or hard disk drive, or any other form of digital storage. The support circuit 214 may be coupled with the CPU 212 and may include cache, clock circuits, input/output systems, power supplies, and any other associated component. Bi-directional communications between the controller 210 and the various components of the substrate processing system 200 may be handled through numerous signal cables collectively referred to as signal buses 218, some of which are illustrated in the figure.

As noted above, the present technology may include one or more additional components or features allowing high pressure and low pressure operations to be performed within the same processing chamber. High pressure processing may utilize high volumes of processing gases as well. To ensure adequate exhausting of materials from the chamber, pumping rings may include apertures sized to accommodate the high flow. Because of asymmetric pumping in some systems, the apertures may be sized and spaced to adjust the flow resistance within the processing chamber and to increase or reduce conductance by adjusting a pressure drop to the exhaust, and which may be performed in order to ensure uniform exhausting at multiple pressure regimes. However, these apertures may not be sized for low flow operation, leading conventional technologies to perform subsequent processing in different chambers.

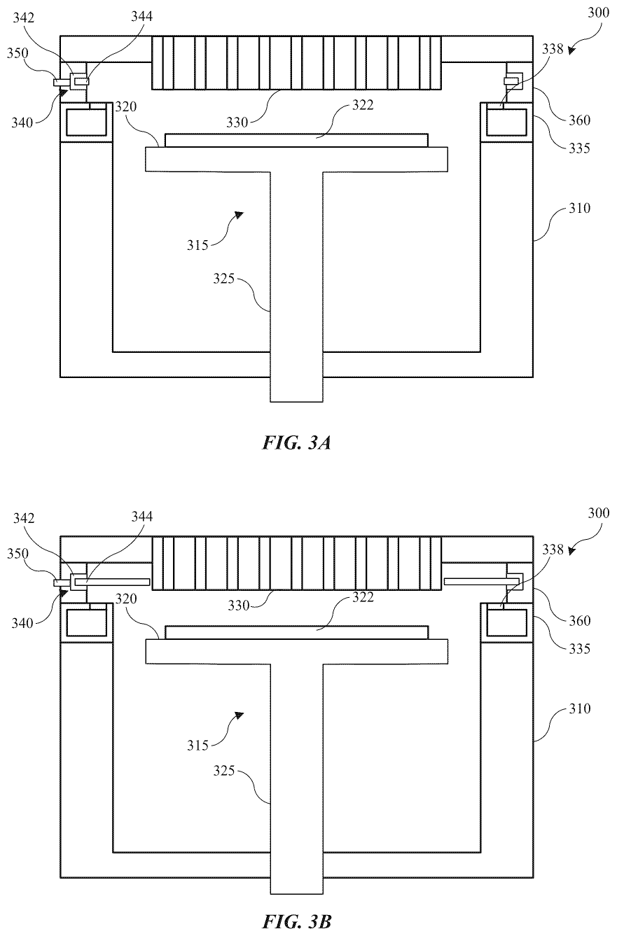

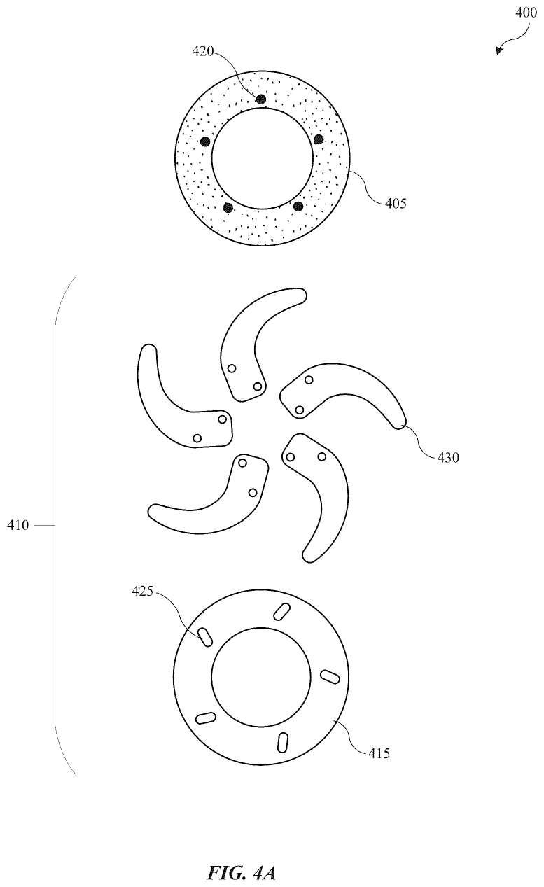

Once a substrate is prepared for a deposition operation, such as including features to be filled with material, or any structure on which deposition may occur, the substrate may be delivered into a processing chamber. An exemplary chamber is illustrated in FIG. 3A, which shows a schematic partial cross-sectional view of a processing system 300 according to some embodiments of the present technology. System 300 may include any aspect of system 200 described above and may illustrate further details relating to components in system 200, such as for an incorporated radial baffle, for example. The system 300 may be used to perform semiconductor processing operations including deposition of materials and treatment of the deposited materials as previously described, as well as other deposition, removal, and cleaning operations.

System 300 may include a chamber body 310, which as illustrated may include sidewalls and a base, as well as a lid in some embodiments as illustrated, all of which may at least partially define an internal volume or processing volume that may include a processing region where a substrate may be processed. A pedestal or substrate support 315 may extend through the base of the chamber into the processing region as previously discussed. The substrate support may include a support platen 320, which may support a semiconductor substrate 322 within the processing region. The support platen 320 may be coupled with a shaft 325, which may extend through the base of the chamber. System 300 may also include a faceplate 330, and the processing region may be at least partially defined between the faceplate 330 and the substrate support 315. For example, the faceplate 330 may define all or a portion of the processing region from above. The faceplate 330 may define a number of apertures through the faceplate through which one or more gases and/or plasmas may be delivered to the processing region. Additionally, system 300 may include a pumping ring 335, which may define a number of apertures 338 sized and spaced in any number of ways to provide a uniform exhaust path from the processing region. Apertures 338 may be defined and extend through an upper surface of the pumping ring 335. Pumping ring 335 may extend circumferentially about the processing region as illustrated and may be located radially outward from the faceplate and the substrate support. For example, a gap may exist between the pumping ring and each or either of the substrate support or the faceplate as illustrated, and as will be discussed further below. As explained previously, symmetric or asymmetric pumping systems may be coupled with the pumping ring 335.

System 300 may also include a radial baffle 340, which may extend about the faceplate 330 as illustrated. The radial baffle 340 may be disposed atop the pumping ring 335, either directly or indirectly via one or more intervening components. For example, as illustrated, the radial baffle 340 is positioned within a liner 360 that is positioned above the pumping ring 335. For example, an inner surface of the liner 360 may define a groove in which the radial baffle 340 may be seated. It will be appreciated that other configurations are possible. For example, the radial baffle 340 may be seated atop the pumping ring 335, seated atop or within a portion of a sidewall of the chamber body 310, and/or positioned atop or within another component of the system 300. Because the radial baffle may be exposed to plasma effluents or other corrosive materials, the radial baffle 340 and/or outer surface thereof may be formed from various materials, such as a chamber chemistry-compatible material, such as a dielectric material and/or chemical-resistant polymer (e.g., a fluorine rubber, polytetrafluoroethylene, etc.). In some embodiments, the radial baffle 340 and/or outer surface of the radial baffle 340 may include ceramics, aluminum, oxidized materials, or coated materials, such as a coated aluminum. Additionally, the baffle may be grounded or at the same potential as the chamber body or substrate support, or otherwise configured to control or limit an effect on plasma conditions during processing. The baffles may also be characterized by any number of shapes or forms conducive to semiconductor processing chambers.

In some embodiments, the entire portion of the radial baffle 340 that is disposed to the process chemistry may be formed from the same material, while in other embodiments the radial baffle 340 and/or components thereof may include a core material and a coating or layer of chamber chemistry-compatible material. For example, the core may be formed from a metal or ceramic material. The radial baffle 340 may have an annular shape in some embodiments and may encircle the processing region. An inner edge of the radial baffle 340 may define a central aperture that may extend about the faceplate 330. As will be discussed in greater detail below, the radius of the central aperture may be adjustable, which may enable the radial baffle 340 to alter the volume of the processing region, which may cause a corresponding change to flow conductance and enable system 300 to be utilized in both low-pressure and high-pressure processing operations. The radial baffle 340 may be positioned above a top surface of the pumping ring 335 by a distance of no greater than 2 cm, no greater than 1.5 cm, no greater than 1 cm, no greater than 0.75 cm, no greater than 0.5 cm, no greater than 0.25 cm, or less, while remaining vertically spaced apart from the top surface of the pumping ring 335. For example, a minimum vertical distance between the top surface of the pumping ring 335 and the radial baffle 340 may be at least 0.05 cm, at least 0.1 cm, or more in some embodiments.

The radial baffle 340 may include a fixed portion 342 that may be coupled with the liner 360 (or other chamber component) and a movable portion 344 that may be radially extendable into the processing region to adjust a radius or other lateral dimension of the central aperture. For example, the movable portion 344 of the radial baffle 340 may be translatable between a first position (shown in FIG. 3A) in which an inner edge of the movable portion 344 of the radial baffle 340 is retracted radially away from the faceplate and a second position (shown in FIG. 3B) in which the inner edge of the movable portion 344 of the radial baffle 340 is extended radially toward the processing region. When the radial baffle 340 is in the first position, an inner edge of the movable portion 344 of the radial baffle 340 may be disposed radially outward of an inner edge of the pumping ring 335. For example, in the first position, the inner edge of the movable portion 344 of the radial baffle 340 may be retracted to a position that is within 2.5 cm of an inner surface of a sidewall of the chamber body 310, within 2 cm of the inner surface, within 1.5 cm of the inner surface, within 1 cm of the inner surface, within 0.5 cm of the inner surface, within 0.25 cm of the inner surface, within 0.1 cm of the inner surface, or less. In some embodiments, in the first position, the inner edge of the movable portion 344 of the radial baffle 340 may be flush with and/or recessed relative to the inner surface of the sidewall of the chamber body 310. This may enable the radial baffle 340 to have minimal or no impact on the process volume and flow conductance when in the first position, which may be particularly useful when the system 300 is being used to perform a high-pressure operation. When the radial baffle 340 is in the second position, the inner edge of the movable portion 344 of the radial baffle 340 may be disposed radially inward of the inner edge of the pumping ring 335 and extends over a top of the apertures 338 of the pumping ring 335, which may enable the radial baffle 340 to reduce a size of the process volume/region and alter an exhaust flow path for gases and plasma radicals from the process region. For example, in the second position, the inner edge of the movable portion 344 of the radial baffle 340 may be extended to a position that is within 2.5 cm of an outer lateral surface of the faceplate 330, within 2 cm of the outer lateral surface, within 1.5 cm of the outer lateral surface, within 1 cm of the outer lateral surface, within 0.5 cm of the outer lateral surface, within 0.25 cm of the outer lateral surface, within 0.1 cm of the outer lateral surface, within 0.05 cm of the outer lateral surface, within 0.025 cm of the outer lateral surface, or less. In some embodiments, in the second position, the inner edge of the movable portion 344 of the radial baffle 340 may be extended inward to contact the outer lateral surface of the faceplate 330, however, some embodiments may maintain the inner edge of the movable portion 344 in a spaced apart relation from the outer lateral surface of the faceplate 330 to eliminate contact that may transmit electrical current and/or generate fall on defects that may contaminate the substrate being processed. For example, the inner edge of the movable portion 344 of the radial baffle 340 may be spaced apart from the outer surface of the faceplate 330 by a distance of between 15 mils and 30 mils, although other distances are possible in various embodiments. The ability to extend the inner edge of the movable portion 344 of the radial baffle 340 to positions proximate the outer lateral surface of the faceplate 330 may enable the radial baffle 340 to reduce the size and shape of the flow path of the process volume, which may reduce flow conductance within the process volume, which may be particularly useful during low pressure processing operations. In some embodiments, the movable portion 344 of the radial baffle 340 may be translatable to any number of radial positions between the first position and the second position to provide greater control over the size of the central aperture. For example, the radial baffle 340 may be extended inward and/or retracted outward in set increments and/or along a smooth gradient of an infinite (or otherwise large) number of radial positions. By providing greater control over the size of the central aperture, greater control over the flow conductance within the processing region may be afforded, which may enable the system 300 to be tuned for use in the performance of any number of processing operations that may be performed across a variety of pressure levels.

System 300 may also include an actuator 350 that may be coupled with the radial baffle 340. For example, actuator 350 may be coupled with the movable portion 344 of the radial baffle 340 and may be used to translate the radial baffle 340 between the first position and the second position, as well as any intermediate positions between the first position and the second position. Any type of actuator 350 may be used to translate the radial baffle 340, such as hydraulic actuators, pneumatic actuators, linear actuators, rotational actuators, and the like. The type of actuator 350 used may depend on the form of the radial baffle 340 and/or the chamber design. In some embodiments, the actuator 350 may be disposed within and/or outside of the chamber body 310. As just one example, all or a portion of the actuator 350 may be disposed within the sidewall of the chamber body 310, with a portion of the actuator 350 being in contact with the movable portion 344 of the radial baffle 340. In other embodiments, at least a portion of the actuator 350 may exist at least partially inside the processing chamber and may be partially or fully contained within the processing chamber.

As noted above, the radial baffle 340 may be extended into the processing space to modify a flow path within the processing region. For example, while the pumping ring apertures 338 may be sized for high-flow conditions, the apertures 338 may not fully provide sufficient resistance to flow for low-flow conditions, which may allow asymmetric pumping to non-uniformly draw from the chamber, and which may cause non-uniformity issues on the substrate based on non-uniform flow of materials. When extended to the second position and/or to an intermediate position in which at least a portion of the radial baffle 340 extends over the apertures 338, the radial baffle 340 may at least partially block flow towards the pumping ring 335, which may increase residence time of low flow materials, and ensure uniformity in treatment and exhausting may be maintained. The radial baffle 340 may be extended towards the faceplate 330 as illustrated in FIG. 3B, and may extend inward beyond an upper surface of the pumping ring 335, and in particular, the apertures 338. This may allow the radial baffle 340 to restrict a flow path to the pumping ring 335, such as by reducing a gap distance between an upper surface of the pumping ring 335 and a lower surface of the radial baffle 340. When the radial baffle 340 is extended into the processing region with at least a portion of the radial baffle 340 being above the apertures 338 of the pumping ring 335, access to the pumping ring 335 may be restricted to a gap distance. By reducing the gap distance, increased flow resistance may be produced toward the pumping ring, which may adequately restrict flow to ensure uniform exhausting during low pressure processing.

In some embodiments, the substrate support 315 may be vertically translated, such as being elevated from a lower position as shown in FIG. 3A towards the faceplate 330 as shown in FIG. 3B, which may further modify the processing region prior to subsequent processing. For example, the substrate support 315 may be in the lower position for high pressure processing operations to the higher position. In some embodiments, with the substrate support 315 in the first position, a first process may be performed on a substrate at a first pressure and, upon completion, the substrate support 315 may be raised to the second position. A subsequent process may then be performed, which may be performed at a second pressure less than the first pressure at which deposition was performed. As one non-limiting example, a plasma treatment of the deposited film may be performed in some embodiments of the present technology. For example, a plasma may be formed of a treatment precursor within the processing region of the semiconductor processing chamber. Although a remote plasma process may be used, in some embodiments a local plasma may be formed in the processing region of the chamber. Continuing the previous non-limiting example, a treatment precursor may be flowed into the processing region and a plasma may be generated of the treatment precursor.

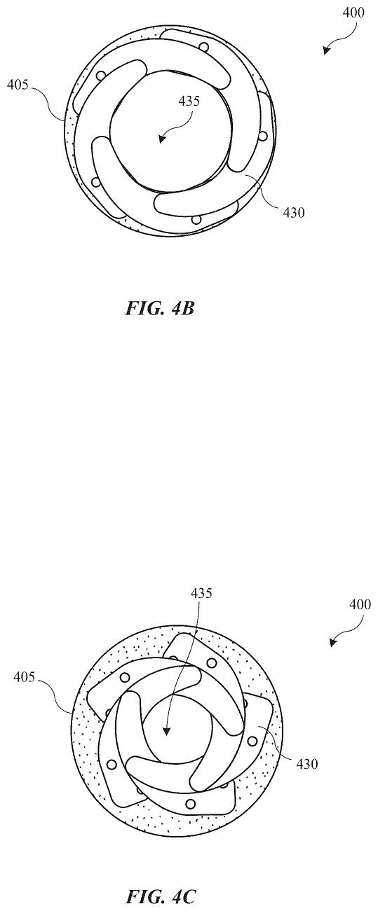

The radial baffles described herein may take various forms. For example, any radial baffle that enables a size of the central aperture to be selectively increased and decreased may be utilized. In some embodiments, the central aperture may be substantially circular at all/most radial positions of the radial baffle to ensure that the radial baffle does not introduce any uniformity issues into the exhaust flow path within the processing region. FIGS. 4A-4C illustrate a particular embodiment of a radial baffle 400 in accordance with the present invention. It will be appreciated that radial baffle 400 is merely provided as one form of radial baffle and that the systems described herein may include radial baffles that take any number of forms. Radial baffle 400 may be used as the radial baffle 340 in some embodiments and may include any of the features described in relation to the radial baffle 340. For example, the radial baffle 400 may include a fixed portion 405, which may be similar to fixed portion 342. The fixed portion 405 may be in the form of a base plate on which a movable portion 410 is mounted.

The movable portion 410 may include a number of components. For example, the movable portion 410 may include an actuating ring 415 and a number of leaves or blades 430. The actuating ring 415 may be mounted on the fixed portion 405 using a number of pins 420 that extend through slots 425 formed through the actuating ring 415. The slots 425 may have longitudinal axes that do not intersect a central axis of the radial baffle 400, with the slots 425 being angled toward the central aperture 435 of the radial baffle 400 such that each slot 425 has a radial inward end and a radial outward end. A degree of the angle of each slot 425 may be selected to control a minimum size of the central aperture 435 (e.g., when the radial baffle 400 ins in the second position). A length of each slot 425 may be selected to control how much the size of the central aperture 435 may be changed between the first position and the second position. The longitudinal axes of each slot 425 may be at different orientations relative to one another to enable the pins 420 to traverse the slots 425 as the actuating ring 415 is rotated relative to the fixed portion 405. For example, the angular difference of the axes of adjacent slots may be uniform for all slots 425 about the actuating ring 415. In some embodiments, each slot 425 may be linear, while in other embodiments each slot 425 may be arcuate in shape.

Each blade 430 may be mounted to both the fixed portion 405 and the actuating ring 415. For example, a first end of each blade 430 may be coupled with one of the pins 420 to couple the blade 430 to the fixed portion 405. The first end of each blade 430 may be fastened to the actuating ring 415 at a position that is spaced apart from the respective pin 420 and is at a different radial position (e.g., radially inward or outward) of the pin 420. The coupling of the blade 430 with both the fixed portion 405 and the actuating ring 415 enables rotation of the actuating ring 415 relative to the fixed portion 405 to move a second end of each blade 430 inward or outward (depending on the direction of rotation) relative to the central axis of the radial baffle 400. For example, as the pins 420 are moved toward the radially outer end of the slot 425, movement of the pin 420 within the slot 425 causes the blade 430 to pivot about the connection with the actuating ring 415 such that the second end of each blade 430 moves radially outward and ultimately out of the processing region as illustrated in FIG. 4B (without actuator ring 415 to show movement of blades 430). As the pins 420 are moved toward the radially inner end of the slot 425, movement of the pin 420 within the slot 425 causes the blade 430 to pivot about the connection with the actuating ring 415 such that the second end of each blade 430 moves radially inward and into the processing region toward the lateral surface of the faceplate as illustrated in FIG. 4C (without actuator ring 415 to show movement of blades 430). The size, shape, and number of blades 430 may be selected to control the shape of the central aperture 435. For example, a greater number of blades 430 having arcuate inner surfaces may be used to generate a substantially circular central aperture 435 at the first position, the second position, and any intermediate position therebetween. Any number of blades 430 may be used. For example, the radial baffle 400 may include five or more blades, six or more blades, seven or more blades, eight or more blades, nine or more blades, 10 or more blades, 12 or more blades, 15 or more blades, 20 or more blades, or more. Circumferentially adjacent blades 430 may be positioned at different heights (e.g., the blades 430 may be positioned in two or more rows) to enable the blades 430 to be moved without jamming. An actuator (such as actuator 350) may be used to move the actuating ring 415 relative to the fixed portion 405 to move the blades 430 to adjust the size of the central aperture 435.

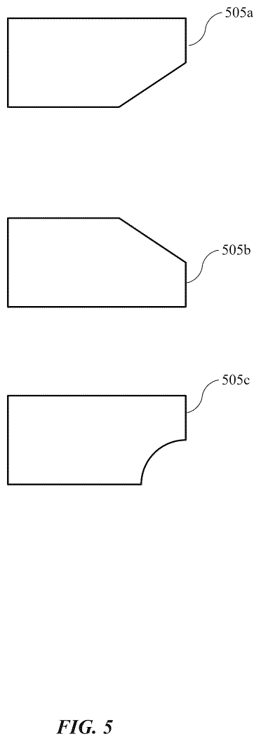

Radial baffles according to embodiments of the present technology may be characterized by features that can further facilitate or develop flow of precursors within the processing chamber. FIG. 5 illustrates exemplary edge treatments that may be formed about a top and/or bottom edge of the radially innermost surface of the movable portion of the radial baffles within the processing region, and which may further tune flow properties within the processing region. For example, dish 505a may include any aspect of any radial baffle discussed above, and may include a lower taper, which may allow precursors delivered through the faceplate to flow without adjusting to a lower corner of the radial baffle. Similarly dish 505b may be characterized by an upper taper. Baffles according to embodiments of the present technology may be characterized by one or more of a lower edge treatment or an upper edge treatment, which may recess material or form a protrusion extending further into the processing region in embodiments of the present technology. Additionally, along with a tapered effect of any degree, baffles may include other shaped interior or exterior profiles, which may include a curved feature as illustrated in first ring 505c. The edge treatments illustrated are not intended to be limiting as any number of profiles may be formed and are encompassed by the present technology. By utilizing a baffle according to embodiments of the present technology, chambers may be used for broad ranges of processing pressures or conditions, while maintaining more uniform flow across the different pressure regimes.

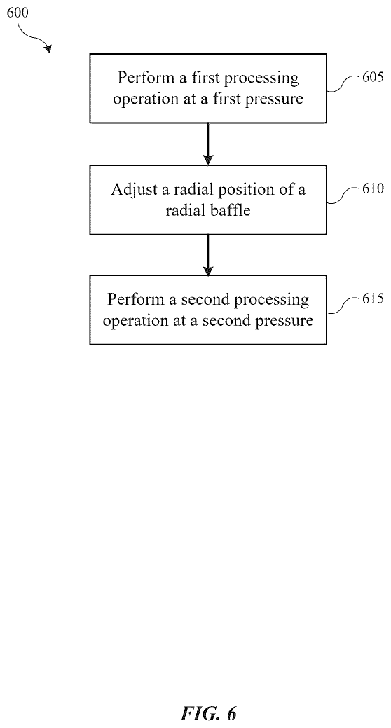

FIG. 6 shows operations of an exemplary method 600 for inspecting a wafer seal chuck assembly according to some embodiments of the present technology. The method may be performed using a variety of processing chambers and systems, including systems 100, 200, and 300 described above, which may include radial baffles according to embodiments of the present technology, such as radial baffles 340 and 400. Method 600 may include a number of optional operations, which may or may not be specifically associated with some embodiments of methods according to the present technology.

Method 600 may include optional operations prior to initiation of method 600, or the method may include additional operations. For example, method 600 may include operations performed in different orders than illustrated. Method 600 may be performed on a substrate that has been positioned within the processing region of a chamber, such as seated on a substrate support. In some embodiments, method 600 may include performing a first processing operation on a substrate disposed within a processing region of a processing chamber at operation 605. The first processing operation may be performed at a first pressure. For example, the first processing operation may include flowing a first precursor into the processing region via a faceplate of the chamber. The first precursor may be used when performing the first processing operation. As just one example, the first processing operation may include delivering one or more deposition precursors into the processing region of the semiconductor processing chamber. A layer of material may be deposited on a substrate disposed within the processing region. In such embodiments, the first pressure may be at least 50 Torr. Other forms of processing operations may be used as the first processing operation in various embodiments.

At operation 610, a radial position of an inner edge of a radial baffle may be adjusted within the processing region relative to a peripheral edge of a faceplate of the processing chamber to modify an exhaust flow path within the processing region. The type of adjustment of the radial baffle may depend on whether the first pressure of the first processing operation is less than or greater than a second pressure of a subsequent processing operation. For example, where the first pressure is higher than the second pressure, adjusting the radial position of the inner edge of the radial baffle may include extending the inner edge of the radial baffle in a radially inward direction toward a peripheral edge of the faceplate. Where the first pressure is lower than the second pressure, adjusting the radial position of the inner edge of the radial baffle may include retracting the inner edge of the radial baffle in a radially outward direction away from a peripheral edge of the faceplate. Continuing the example in which the first processing operation involves delivering deposition precursors into the processing region, the radial baffle may be extended into the processing region only a portion of a distance to a peripheral edge of a faceplate through which the deposition precursor is delivered. In some embodiments, the radial baffle may be partially or fully retracted while the layer of material is deposited on the substrate.

Method 600 may include performing a second processing operation on the substrate at operation 615. The second processing operation may be performed at the second pressure that is different than the first pressure. In some embodiments, the second processing operation may include flowing a second precursor into the processing region via the faceplate, with the second precursor being used when performing the second processing operation. As just one example, the second processing operation may include forming a plasma of a treatment precursor within the processing region. The layer of material deposited on the substrate may be treated with plasma effluents of the treatment precursor. In such embodiments, the second pressure may be less than 20 Torr. Other forms of processing operations may be used as the second processing operation in various embodiments. In some embodiments, subsequent to depositing the layer of material on the substrate, moving the substrate towards a faceplate of the semiconductor processing chamber. For example, during the first processing operation, a distance between the faceplate and the substrate support may be between about 320 mils and 360 mils, while during the second processing operation the distance between the faceplate and the substrate support may be between 280 mils and 320 mils. The first processing operation may include a deposition, an etch, a treatment, or an anneal operation while the second processing operation includes a different one of a deposition, an etch, a treatment, or an anneal operation. A lower pressure operation may include a pressure of no greater than 20 Torr, while a higher pressure operation may include a pressure of at least 50 Torr.

Any variety of deposition processing may be performed in embodiments of the present technology, including plasma and non-plasma deposition operations, and in one encompassed embodiment, a sub-atmospheric chemical vapor deposition process may be performed. For example, the one or more precursors may be thermally decomposed to deposit material on the substrate. The process may occur at any temperature, such as greater than or about 200° C., and may occur at greater than or about 250° C., greater than or about 300° C., greater than or about 350° C., greater than or about 400° C., greater than or about 450° C., greater than or about 500° C., greater than or about 550° C., greater than or about 600° C., or higher.

As noted above, the method 600 may include a layer of material may be deposited on the substrate. Although the process may occur at any processing pressure, in some embodiments the process may occur at a first processing pressure, which may be a relatively higher processing pressure. For example, in some embodiments, the first pressure, or a chamber pressure during the deposition, may be greater than or about 50 Torr, and may be greater than or about 100 Torr, greater than or about 150 Torr, greater than or about 200 Torr, greater than or about 250 Torr, greater than or about 300 Torr, greater than or about 350 Torr, greater than or about 400 Torr, greater than or about 450 Torr, greater than or about 500 Torr, greater than or about 550 Torr, greater than or about 600 Torr, or higher. During these higher-pressure processes, a flow rate of one or more deposition precursors may be higher to provide adequate material for deposition. For example, the total flow rate during deposition may be greater than or about 1 slm, and may be greater than or about 5 slm, greater than or about 10 slm, greater than or about 15 slm, greater than or about 20 slm, greater than or about 25 slm, greater than or about 30 slm, greater than or about 35 slm, greater than or about 40 slm, greater than or about 45 slm, greater than or about 50 slm, greater than or about 55 slm, greater than or about 60 slm, or higher.

The present technology may not be limited to any particular deposition process and may be used in any number of deposition processes, including silicon-containing materials, carbon-containing materials, oxygen-containing materials, nitrogen-containing materials, or any other material that may be deposited during semiconductor processing. As one non-limiting example, in some embodiments a sub-atmospheric deposition may be performed for silicon oxide formation. The process may include any number of precursors, such as a silicon-containing precursor, such as silane, tetraethyl orthosilicate, or any other silicon-containing material. Diatomic oxygen, ozone, nitrous oxide, or any other oxygen-containing precursor, as well as any other oxidizer, may be provided, as well as one or more carrier and/or inert gases, such as nitrogen, argon, or any other material. The flow may be greater than or about 20 slm, greater than or about 30 slm, or more, and the processing pressure may be greater than or about 400 Torr, greater than or about 500 Torr, or more. Again, one of skill would readily appreciate that any number of other deposition processes could similarly be performed in systems according to embodiments of the present technology.

As explained previously, the systems described herein may be configured to accommodate the higher pressure, higher flow rate processes of deposition, which may include larger apertures about the pumping ring, and any number of other chamber or system features to accommodate these processing conditions. Because the system may be configured to accommodate high-flow, high-pressure processing, a radial baffle may not be needed during the deposition operations. For example, the radial baffle may be fully retracted within the processing region during the deposition operation and may have limited or no impact on processing during the deposition operations. However, once deposition has been completed, the radial baffle may be used to facilitate lower pressure plasma treatment or any subsequent processing that may occur at a different processing pressure, and which may be encompassed by embodiments of the present technology.

For example, once deposition has been completed, delivery of one or more of the deposition precursors may be halted, and in some embodiments flow of all of the deposition precursors may be halted. The processing region may then be adjusted in preparation for a subsequent treatment operation. For example, the radial baffle may be extended at least partially into the processing region. The radial baffle may be extended into the processing space to modify a flow path within the processing region. For example, while the pumping ring apertures may be sized for high-flow conditions, the apertures may not fully provide sufficient resistance to flow for low-flow conditions, which may allow asymmetric pumping to non-uniformly draw from the chamber, and which may cause non-uniformity issues on the substrate based on non-uniform flow of materials. The radial baffle may at least partially block flow towards the apertures of the pumping ring, which may increase residence time of low-flow materials, and ensure uniformity in treatment and exhausting may be maintained.

After the deposition operation, a subsequent process may then be performed, which may be performed at a second pressure less than the first pressure at which deposition was performed. As one non-limiting example, a plasma treatment of the deposited film may be performed in some embodiments of the present technology. For example, a plasma may be formed of a treatment precursor within the processing region of the semiconductor processing chamber. Although a remote plasma process may be used, in some embodiments a local plasma may be formed in the processing region of the chamber. Continuing the previous non-limiting example, a treatment precursor may be flowed into the processing region and a plasma may be generated of the treatment precursor. The layer of material may be deposited on the substrate may be treated with plasma effluents of the treatment precursor.

As explained previously, the treatment or etching operations may be performed at a second pressure less than the first, which in some embodiments may be an order of magnitude lower pressure, for example. The treatment operation may be performed at a second pressure, which may be less than the first pressure at which deposition was performed, and which may be less than or about 100 Torr, and may be less than or about 75 Torr, less than or about 50 Torr, less than or about 30 Torr, less than or about 20 Torr, less than or about 15 Torr, less than or about 12 Torr, less than or about 10 Torr, less than or about 8 Torr, less than or about 6 Torr, less than or about 4 Torr, less than or about 3 Torr, less than or about 2 Torr, less than or about 1 Torr, less than or about 0.5 Torr, or less. Additionally, the treatment precursor or precursors may be flowed at a total flowrate of less than or about 20 slm, and may be flowed at a rate of less than or about 15 slm, less than or about 12 slm, less than or about 10 slm, less than or about 8 slm, less than or about 6 slm, less than or about 4 slm, less than or about 2 slm, less than or about 1 slm, less than or about 0.5 slm, or less. Precursors used in treatment and/or etching operations may be or include halogen-containing precursors, such as fluorine or chlorine containing precursors, oxygen-containing precursors, hydrogen-containing precursors, nitrogen-containing precursors, carrier or inert gases, or any number of additional materials.

Continuing the non-limiting example, helium, argon, or some other material may be flowed into the processing region and a plasma may be formed to produce helium plasma effluents, which may interact with the deposited film. This may densify or improve the quality of the film previously deposited. This low pressure, low flow treatment relative to the deposition may not allow the apertures of the pumping liner to control the flow from the chamber. However, with the extended radial baffle, residence time may be increased, and a restriction in the flow path between the radial baffle and the apertures of the pumping ring may facilitate uniform exhaust from the chamber. Accordingly, the present technology may allow uniform deposition and treatment to be performed within the same processing chamber across a wide pressure differential.

Similarly, or additionally, an etch process may be performed utilizing a halogen-containing material as noted above, which may be delivered at any of the flows or pressures described above, and which may occur at a lower total flow rate than a treatment operation. Much like the treatment described above, this low pressure, low flow etch may require increased flow resistance to the exhaust. Again, the radial baffle may be raised to a similar or different position as in the treatment, which may accommodate the flow and pressure regime for the etch process. In embodiments of the present technology, flow conductance can be controlled by adjusting flow resistance to the exhaust, which may be performed dynamically with the position of the radial baffle. This may allow any number of operations to be accommodated in a single chamber across a wide range of conditions.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of +20% or +10%, +5%, or +0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system comprising:
a chamber body comprising sidewalls and a base, the chamber body defining a processing region;
a substrate support extending through the base of the chamber body, wherein the substrate support is configured to support a substrate within the processing region;
a faceplate defining a plurality of apertures through the faceplate, wherein the faceplate defines the processing region from above;
a pumping ring extending about the processing region and providing an exhaust path from the processing region; and
a radial baffle extending about the faceplate, the radial baffle being translatable between a first position in which the radial baffle is retracted radially away from the faceplate and a second position in which the radial baffle is extended radially toward the processing region.

2. The semiconductor processing system of claim 1, wherein:
when the radial baffle is in the first position, an inner edge of the radial baffle is disposed radially outward of an inner edge of the pumping ring; and
when the radial baffle is in the second position, the inner edge of the radial baffle is disposed radially inward of the inner edge of the pumping ring.

3. The semiconductor processing system of claim 1, wherein:
the radial baffle comprises an annular shape.

4. The semiconductor processing system of claim 1, wherein:
the radial baffle is translatable to a plurality of radial positions between the first position and the second position.

5. The semiconductor processing system of claim 1, wherein:
in the second position, an inner edge of the radial baffle is spaced apart from an outer surface of the faceplate by a distance of between 15 mils and 30 mils.

6. The semiconductor processing system of claim 1, wherein:
the radial baffle comprises a dielectric material.

7. The semiconductor processing system of claim 1, further comprising:
an actuator that is coupled with the radial baffle, the actuator being configured to translate the radial baffle between the first position and the second position.

8. The semiconductor processing system of claim 7, wherein:
the actuator comprises at least one of a hydraulic actuator, a pneumatic actuator, or a linear actuator.

9. The semiconductor processing system of claim 1, wherein:
the pumping ring defines a plurality of pumping apertures that extend through an upper surface of the pumping ring and that are fluidly coupled with the exhaust path.

10. A method of semiconductor processing comprising:
delivering a deposition precursor into a processing region of a semiconductor processing chamber;
depositing a layer of material on a substrate disposed within the processing region, wherein the processing region is maintained at a first pressure during the depositing;
extending a radial baffle into the processing region in a radially inward direction, wherein the radial baffle modifies an exhaust flow path within the processing region;
forming a plasma of a treatment precursor within the processing region, wherein the processing region is maintained at a second pressure during the forming; and
treating the layer of material deposited on the substrate with plasma effluents of the treatment precursor.

11. The method of semiconductor processing of claim 10, wherein:
the radial baffle is retracted while the layer of material is deposited on the substrate.

12. The method of semiconductor processing of claim 10, wherein:
the first pressure is at least 50 Torr; and
the second pressure is no greater than 20 Torr.

13. The method of semiconductor processing of claim 10, further comprising:
subsequent to depositing the layer of material on the substrate, moving the substrate towards a faceplate of the semiconductor processing chamber.

14. The method of semiconductor processing of claim 10, wherein:
extending the radial baffle into the processing region comprises extending the radial baffle only a portion of a distance to a peripheral edge of a faceplate through which the deposition precursor is delivered.

15. A method of semiconductor processing comprising:
performing a first processing operation on a substrate disposed within a processing region of a processing chamber, wherein the first processing operation is performed at a first pressure;
adjusting a radial position of an inner edge of a radial baffle within the processing region relative to a peripheral edge of a faceplate of the processing chamber to modify an exhaust flow path within the processing region; and
performing a second processing operation on the substrate, wherein the second processing operation is performed at a second pressure that is different than the first pressure.

16. The method of semiconductor processing of claim 15, further comprising:
flowing a first precursor into the processing region via the faceplate, wherein the first precursor is used when performing the first processing operation; and
flowing a second precursor into the processing region via the faceplate, wherein the second precursor is used when performing the second processing operation.

17. The method of semiconductor processing of claim 15, wherein:
the first pressure is higher than the second pressure; and
adjusting the radial position of the inner edge of the radial baffle comprises extending the inner edge of the radial baffle in a radially inward direction toward a peripheral edge of the faceplate.

18. The method of semiconductor processing of claim 15, wherein:
the first pressure is lower than the second pressure; and
adjusting the radial position of the inner edge of the radial baffle comprises retracting the inner edge of the radial baffle in a radially outward direction away from a peripheral edge of the faceplate.

19. The method of semiconductor processing of claim 15, wherein:
one of the first pressure and the second pressure is at least 50 Torr and the other of the first pressure and the second pressure is no greater than 20 Torr.

20. The method of semiconductor processing of claim 15, wherein:
the first processing operation comprises one of deposition, etch, treat, anneal; and the second processing operation comprises a different one of deposition, etch, treat, anneal.
